(19) United States
(12) Patent Application Publication
(10) Pub. No.: US 2025/0062269 A1
(43) Pub. Date: Feb. 20, 2025

(54) SEMICONDUCTOR DEVICES WITH NON-CONDUCTIVE FILM RETENTION ARRANGEMENTS, AND ASSOCIATED ASSEMBLIES AND METHODS

(71) Applicant: Micron Technology, Inc., Boise, ID (US)

(72) Inventors: Kai Chieh Wang, Hsinchu City (TW); Chia Ching Chen, Taichung (TW)

(21) Appl. No.: 18/788,814

(22) Filed: Jul. 30, 2024

Related U.S. Application Data
(60) Provisional application No. 63/533,013, filed on Aug. 16, 2023.

(51) Int. Cl. H01L 23/00; H01L 23/31; H01L 23/498; H01L 25/00; H01L 25/065; H10B 80/00

(52) U.S. Cl. CPC H01L 24/32; H01L 24/16; H01L 24/73; H01L 24/81; H01L 24/83; H01L 24/92; H01L 25/0657; H01L 23/3107; H01L 23/49822; H01L 24/17; H01L 24/33; H01L 25/50; H01L 2224/16145; H01L 2224/16221; H01L 2224/17181; H01L 2224/26145; H01L 2224/32145; H01L 2224/32221; H01L 2224/33181; H01L 2224/73204; H01L 2224/81203; H01L 2224/83007; H01L 2224/83203; H01L 2224/92125; H01L 2225/06513; H10B 80/00

(57) ABSTRACT

A semiconductor device assembly is provided, which comprises a vertical stack of semiconductor devices, the vertical stack including a plurality of electrical interconnects, a plurality of retention structures, and a non-conductive film (NCF) between each adjacent pair of semiconductor devices of the vertical stack. The plurality of retention structures between each adjacent pair of semiconductor devices is disposed peripherally to the corresponding plurality of electrical interconnects. Each of the plurality of retention structures has a height less than a space between the corresponding adjacent pair of semiconductor devices, and the plurality of retention structures between each adjacent pair of semiconductor devices has a smaller first average pitch between adjacent ones of the plurality of retention structures than a second average pitch between adjacent ones of the corresponding plurality of electrical interconnects.

### CROSS-REFERENCE TO RELATED APPLICATION(S)

The present application claims priority to U.S. Provisional Patent Application No. 63/533,013, filed Aug. 16, 2023, the disclosure of which is incorporated herein by reference in its entirety.

### TECHNICAL FIELD

The present technology generally relates to semiconductor device assemblies, and, more specifically, to semiconductor device assemblies with non-conductive film retention arrangements.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a side, cross-sectional view of a semiconductor device assembly with non-conductive film squeeze-out.

FIG. 2 is a side, cross-sectional view of a semiconductor device assembly including retention arrangements, configured in accordance with some embodiments of the present technology.

FIG. 3 is a top, cross-sectional view of a semiconductor device assembly including a retention arrangement, configured in accordance with some embodiments of the present technology.

FIG. 4-7 are top cross-sectional views of semiconductor devices assemblies illustrating retention arrangement regions, configured in accordance with some embodiments of the present technology.

FIG. 8 is a schematic diagram illustrating a semiconductor device assembly incorporating the present technology, configured in accordance with some embodiments of the present technology.

FIG. 9 is a flow diagram illustrating a process for producing a semiconductor device assembly with a retention arrangement in accordance with some embodiments of the present technology.

The drawings have not necessarily been drawn to scale. Similarly, some components or operations can be separated into different components or combined into a single assembly in some implementations of the present technology. While the technology is amenable to various modifications and alternative forms, specific implementations have been shown by way of example in the drawings and are described in detail below.

### DETAILED DESCRIPTION

Semiconductor device assemblies or packages with stacked devices therein can include a stack of multiple, interconnected semiconductor devices. Between the stacked devices, these assemblies include a filler material to protect the devices from impurities in the environment and to improve structural integrity of the device stack overall. One such filler material is non-conductive film (NCF), a sheet of flexible material applied to an outer (e.g., top or bottom) surface of the stacked devices. The applied NCF fills the gap between physically and electrically connected stacked devices, protecting the stacked devices, while allowing interconnection structures between the stacked devices to extend therethrough. However, during assembly, when a device stack including NCF is heated and compressed to finalize the device stack, NCF material can unpredictably extend out (e.g., squeeze out) from sides of the device stack. Among other concerns, this NCF squeeze-out can (i) undesirably increase the size and/or modify the appearance of the device stack; (ii) create voids between the NCF squeeze-out and a side of the device stack, potentially trapping impurities therein; and (iii) prevent a later-applied mold material from reaching the sides of the device.

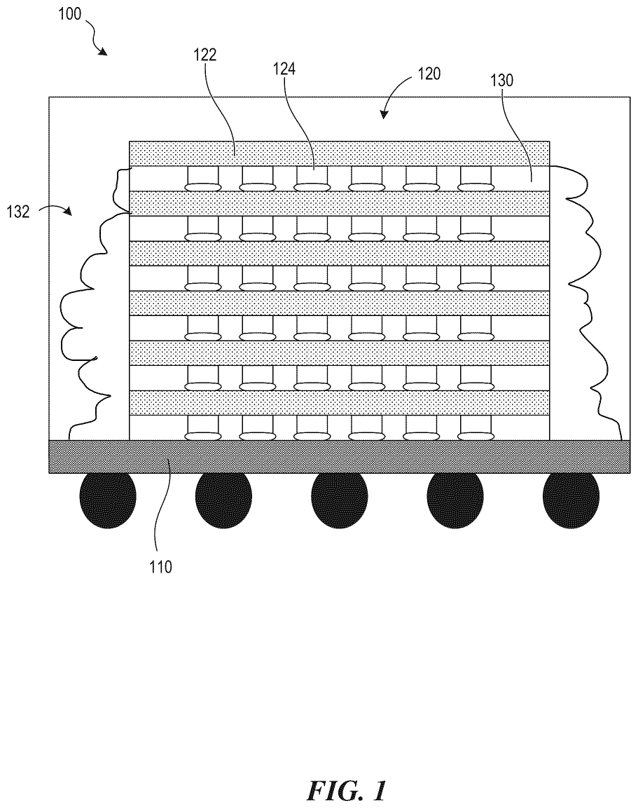

FIG. 1 is a side, cross-sectional view of a semiconductor device assembly 100 illustrating NCF squeeze-out, and some concerns thereof. The assembly 100 of FIG. 1 includes a substrate 110 having a semiconductor device stack 120 with multiple stacked semiconductor devices 122 therein. An NCF 130 is provided to separate and protect adjacent ones of the stacked devices 122, with interconnection structures 124 between the stacked devices 122 extending through the NCF 130. As shown in FIG. 1, a squeeze-out portion 132 of the NCF 130 extends from the left side of the device stack 120. The squeeze-out portion 132 is part of the NCF 130 that, during bonding of the device stack 120, escaped from between the stacked devices 122 to the outside of the device stack 120. That is, when the device stack 120 was heated and compressed, the squeeze-out portion 132 “squeezed out” from between the stacked devices 122 as the space between adjacent ones of the stacked devices 122 was decreased by the bonding operation.

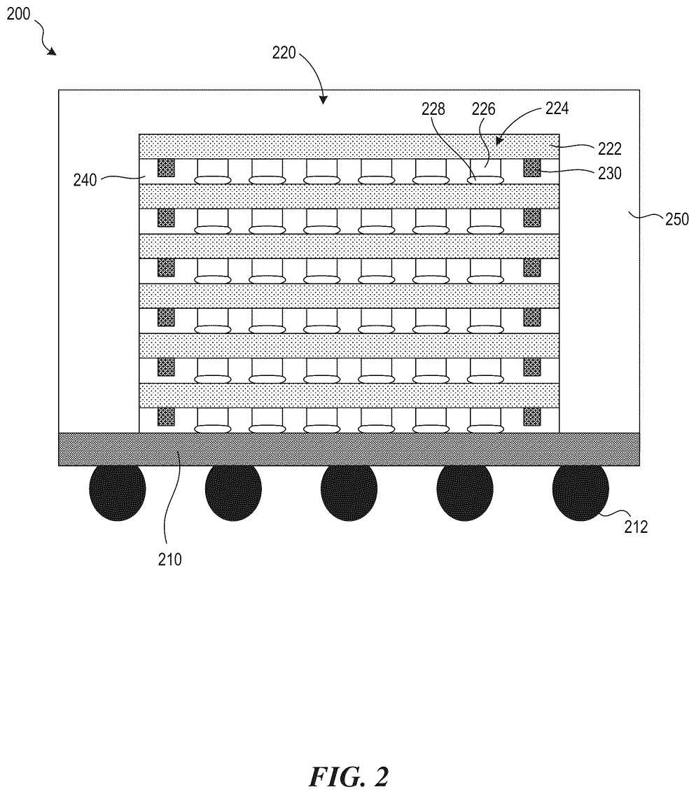

FIG. 2 is a side, cross-sectional view of a semiconductor device assembly 200 including retention arrangements, configured in accordance with some embodiments of the present technology. More specifically, the illustrated assembly 200 includes a substrate 210 with a top surface and a bottom surface opposite the top. A semiconductor device stack 220 is coupled to the top surface and multiple solder balls 212 may be coupled to the bottom surface. The device stack 220 includes multiple stacked semiconductor devices 222 that are physically and electrically interconnected by multiple interconnection structures 224, each having, e.g., an interconnection pillar 226 and an interconnection solder 228.

The substrate 210 can be a package-level substrate upon which other semiconductor devices are carried (e.g., coupled to, bonded to, attached to, adhered to, etc.). For example, the substrate 210 can be a printed circuit board (PCB), an interposer, or another semiconductor device having functional features therein (e.g., a memory controller, a graphics processing unit, a general purpose logic unit, a deep learning accelerator, etc.). According to one aspect of the present disclosure, the substrate 210 and/or each of the stacked devices 222 can be a memory and/or processing device, such as a memory die (e.g., a NAND die, a DRAM die, a NOR die, a PCM die, a FeRAM die, etc.), a graphics processing unit, a logic device, an interposer, a PCB, or any similar semiconductor device with functional features configured to facilitate operation of the assembly 200. The substrate 210 can include substrate bond pads (not illustrated) at the upper and/or lower surface and in electric communication with one or more functional features within the substrate 110. Traces can extend between two or more of the substrate bond pads and/or one or more of the functional features within the substrate 110. Interconnection solder 228 of the device stack 220 can be coupled to the substrate bond pads so that the substrate bond pads, traces, and solder balls 212 can allow communication (e.g., electric communication, interconnection) between the device stack 220 and elements external to the assembly 200.

In accordance with one embodiment of the present disclosure, the stacked devices 222 can each include a retention arrangement having multiple retention structures 230 on a bottom surface thereof. An NCF 240 fills the vertical separation gap between adjacent ones of the stacked devices 222, and the substrate 210, the devices stack 220, and/or any additional elements on the top surface of the substrate 210 are encased in a mold and/or epoxy material 250. As shown, the retention structures 230 coupled to each stacked device 222 extend partially, but not completely, across the separation gap between the stacked device 222 and the surface facing thereto (e.g., another stacked device 222, or the substrate 210), and are laterally positioned between one or more outermost interconnection structures 224 and a sidewall of the respective stacked device 222. During an operation to bond the device stack 220, the stacked devices 220 and the NCF 240 are repeatedly, sequentially layered onto the substrate 210. Once the desired number of stacked devices 222 is reached, the device stack 220 is heated and a pressure is applied to the top thereof to physically and electrically coupled the stacked devices 222 by reflowing each interconnection solder 228 to bond the corresponding interconnection pillar 226 to a facing contact pad or UBM (not illustrated). During this operation, as the space under each of the stacked devices 222 is reduced, NCF 240 may be squeezed toward the sidewalls of the stacked devices 222 and the sides of the device stack 220, generally. Although the amount of NCF 240 provided under each of the stacked devices 222 is carefully metered to correspond to a remaining volume of space following the bonding operation, the flow of NCF 240 is largely radial, which would tend, in the absence of the retention structures 230, to cause squeeze-out near the middle of each sidewall while leaving corner regions under each of the stacked devices 222 potentially free from NCF 240. The retention structures 230 of the retention arrangements, however, constrain and/or slow the flow of NCF 240, redirecting the flow direction towards desired regions (e.g., corners, sidewalls where excess NCF 240 squeezing out will not negatively impact assembly, etc.) under each of the stacked devices 222.

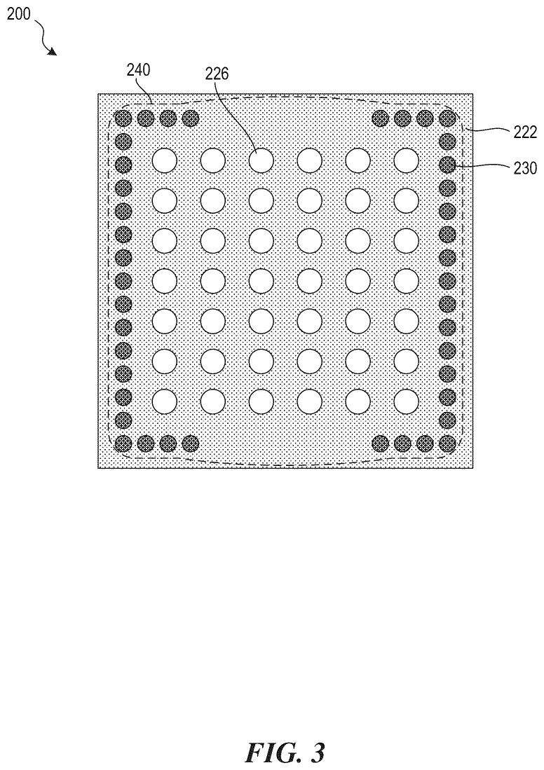

This redirection of NCF may be more easily understood with reference to FIG. 3, which illustrates a top, cross-sectional view of semiconductor device assembly 200 in accordance with some embodiments of the present technology. As can be seen with reference to FIG. 3, the arrangement in this example embodiment of retention structures 230, which are implemented as partial-height pillars (e.g., having a height less than a distance between the bottom surface of a stacked device 222 and a surface facing thereto), includes two generally “C-shaped” regions near opposing sidewalls of the device 222, peripheral to the array of interconnect pillars 226. NCF 240, following the bonding operation described in greater detail above, will accordingly flow radially outward until encountering the retention structures 230, which will slow the flow of NCF 240 past the retention structures 230, such that the flow is redirected through regions proximate the top and bottom sidewalls that are free from retention structures 230. Such an arrangement can ensure that the entire array of interconnect pillars 226, including those proximate corner regions of the device 222, are completely surrounded by NCF 240, while restricting any “squeeze-out” to regions where such squeeze-out may have less of a negative impact (e.g., adjacent sides of the device stack 220 where additional space, free from other semiconductor devices, is available in the assembly 200).

As shown in FIG. 3, the arrangement of retention structures 230 includes a plurality of similarly-sized retention structures 230 with similar spacing between adjacent ones thereof. The dimensions of the retention structures 230, the spacing between adjacent retention structures 230, and the height of the retention structures 230, can all be selected based upon a desired amount of flow restriction for an NCF 240 of some predetermined viscosity. In various embodiments, the retention structures 230 may be cylindrical pillars with diameters between 5 and 200 μm, the spacing between adjacent pillars may be between 5 and 200 μm, and the height of the retention structures may be between 5 and 50 μm. The spacing between adjacent retention structures 230 can be expressed as a fraction or multiple of the critical dimension/diameter of each retention structure—for example, the spacing between adjacent retention structures 230 may be from 1/10th to 10× the diameter of the retention structures. The height of the retention structures 230 can be expressed as a percentage of the post-bonding distance between a stacked device 222 and a surface facing thereto—for example, the height of the retention structures 230 may be from 5% to 90% of the surface-to-surface distance.

According to one aspect of the present disclosure, the retention structures 230 can be implemented as thermal pillars, comprising a thermally conductive metal such as copper, gold, silver, aluminum, or some alloy thereof. Alternatively, the retention structures 230 can comprise a non-conductive material such as solder resist, mold material, or the like, or can even comprise semiconductor materials such as silicon (e.g., silicon spacers).

Although in the foregoing example embodiments, retention structures 230 have been described and illustrated as similarly-sized, similarly-spaced, and with a common height, in other embodiments retention structures may be implemented with a variety of sizes, spacings, and heights. Similarly, retention structures may all comprise a same material composition, or may be implemented with different materials for different retention structures. Although illustrated as being disposed in a single line, in other embodiments retention structures may be implemented as an array of multiple rows and columns in a region, or hexagonally close-packed, or in a variety of other space-occupying arrangements suitable to restrict the flow of an NCF. Although illustrated as pillars with generally circular cross sections, in other embodiments retention structures may have other shapes (or mixtures of shapes), including rectangular prisms, oval cylinders, partial spheroids, etc.

In accordance with one aspect of the subject disclosure, retention structures 230 may be formed by patterning a photoresist over one of the stacked devices before, during, or after the formation of the interconnection structures 224 and depositing a material into the patterned openings of the photoresist to form the retention structures 230.

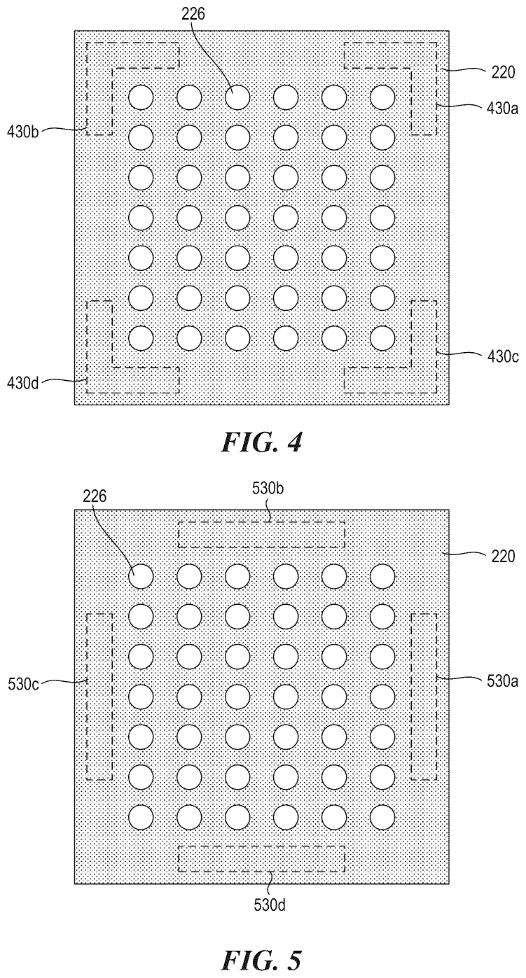

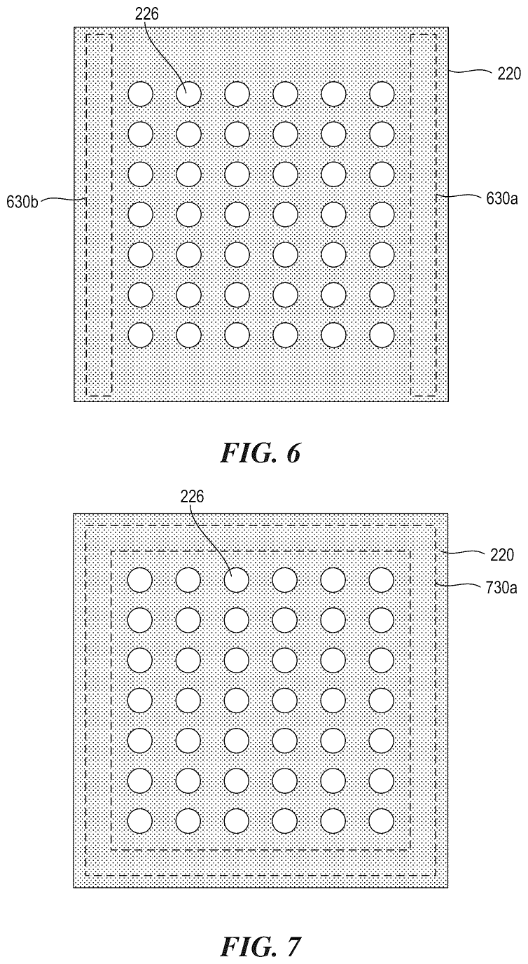

While the embodiment of FIG. 3 illustrates a device 222 with two generally “C-shaped” regions of retention structures proximate opposing sidewalls, in other embodiments other arrangements of regions of retention structures may be implemented. For example, FIGS. 4 through 7 are top cross-sectional views of semiconductor devices assemblies illustrating retention arrangement regions, configured in accordance with various other embodiments of the present technology. Turning to FIG. 4, the arrangement of retention structures can include four generally chevron-shaped regions 430a-430d proximate the corners of the stacked device 222, peripheral to the array of interconnect pillars 226. In FIG. 5, by way of contrast, the arrangement of retention structures can include four generally linear regions 530a-530d proximate the middle of each sidewall of the stacked device 222, peripheral to the array of interconnect pillars 226. In FIG. 6, the arrangement of retention structures can include two generally linear regions 630a and 630b proximate opposing sidewalls of the stacked device 222, peripheral to the array of interconnect pillars 226, and extending substantially (e.g., at least 90% of) the length of the proximate sidewalls. In FIG. 7, yet another arrangement of retention structures is illustrated, with a singular rectangular annulus region 730a proximate to the sidewalls of the stacked device 222, surrounding the array of interconnect pillars 226.

In accordance with one aspect of the present disclosure, the semiconductor devices illustrated in the assemblies of FIGS. 2-7 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby). For example, in one embodiment, a semiconductor device assembly can include a high bandwidth memory (HBM) device including a plurality of memory dies (e.g., 4 memory dies, 8 memory dies, 12 memory dies, 16 memory dies, 32 memory dies, etc.) stacked over a logic die.

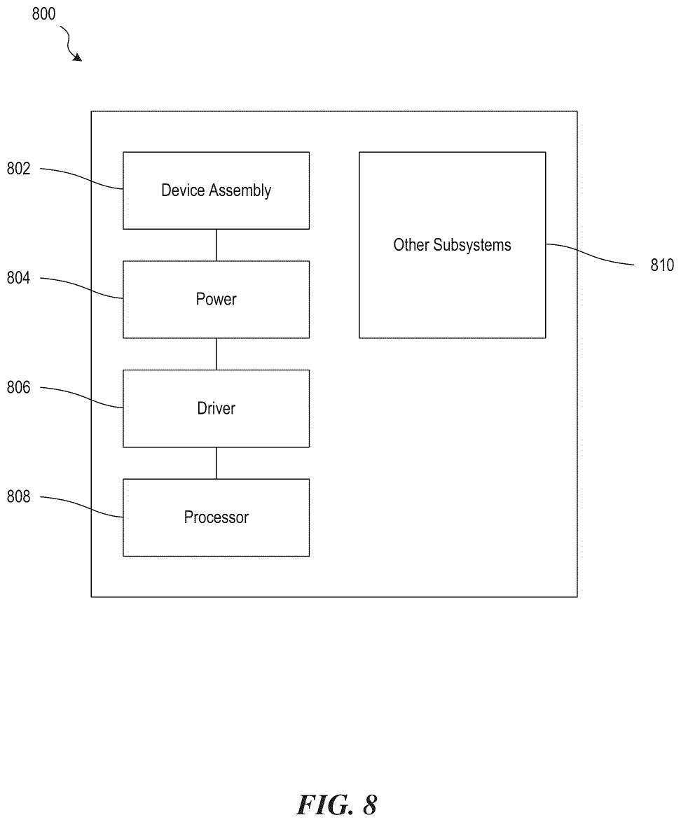

Any one of the semiconductor devices and semiconductor device assemblies described above with reference to FIGS. 2-7 can be incorporated into any of a myriad of larger and/or more complex systems, a representative example of which is system 800 shown schematically in FIG. 8. The system 800 can include a semiconductor device assembly (e.g., or a discrete semiconductor device) 802, a power source 804, a driver 806, a processor 808, and/or other subsystems or components 810. The semiconductor device assembly 802 can include features generally similar to those of the semiconductor devices described above with reference to FIGS. 2-10. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances and other products. Components of the system 800 may be housed in a single unit or distributed over multiple, interconnected units (e.g., through a communications network). The components of the system 800 can also include remote devices and any of a wide variety of computer readable media.

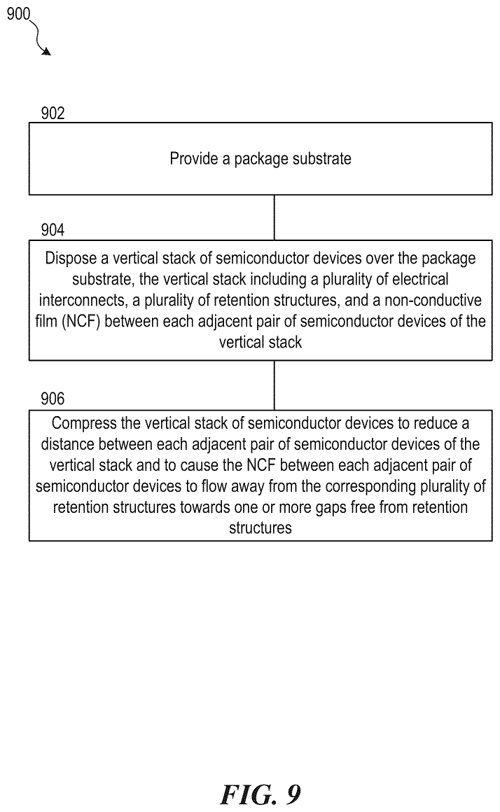

FIG. 9 is a flow chart illustrating a method of making a semiconductor device assembly. The method includes providing a package substrate (box 910) and disposing a vertical stack of semiconductor devices over the package substrate, the vertical stack including a plurality of electrical interconnects, a plurality of retention structures, and a non-conductive film (NCF) between each adjacent pair of semiconductor devices of the vertical stack (box 920). The method further includes compressing the vertical stack of semiconductor devices to reduce a distance between each adjacent pair of semiconductor devices of the vertical stack and to cause the NCF between each adjacent pair of semiconductor devices to flow away from the corresponding plurality of retention structures towards one or more gaps free from retention structures (box 930). The plurality of retention structures between each adjacent pair of semiconductor devices is disposed peripherally to the corresponding plurality of electrical interconnects, each of the plurality of retention structures has a height less than the distance between the corresponding adjacent pair of semiconductor devices following the compressing, and the plurality of retention structures between each adjacent pair of semiconductor devices has a smaller first average pitch between adjacent ones of the plurality of retention structures than a second average pitch between adjacent ones of the corresponding plurality of electrical interconnects.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

We claim:

1. A semiconductor device assembly, comprising:
a vertical stack of semiconductor devices, the vertical stack including a plurality of electrical interconnects, a plurality of retention structures, and a non-conductive film (NCF) between each adjacent pair of semiconductor devices of the vertical stack,
wherein the plurality of retention structures between each adjacent pair of semiconductor devices is disposed peripherally to the corresponding plurality of electrical interconnects,
wherein each of the plurality of retention structures has a height less than a space between the corresponding adjacent pair of semiconductor devices, and
wherein the plurality of retention structures between each adjacent pair of semiconductor devices has a smaller first average pitch between adjacent ones of the plurality of retention structures than a second average pitch between adjacent ones of the corresponding plurality of electrical interconnects.

2. The semiconductor device assembly of claim 1, wherein the plurality of retention structures between each adjacent pair of semiconductor devices includes a first region at a first peripheral edge of the vertical stack, and a second region at a second peripheral edge of the vertical stack opposite the first peripheral edge.

3. The semiconductor device assembly of claim 2, wherein a third region at a third peripheral edge of the vertical stack between each adjacent pair of semiconductor devices includes a gap free of retention structures.

4. The semiconductor device assembly of claim 3, wherein the gap is at least 25% of a length of the third peripheral edge.

5. The semiconductor device assembly of claim 3, wherein a fourth region at a fourth peripheral edge of the vertical stack between each adjacent pair of semiconductor devices includes another gap free of retention structures.

6. The semiconductor device assembly of claim 1, wherein the vertical stack further includes another plurality of electrical interconnects, another plurality of retention structures, and another non-conductive film (NCF) under a bottom semiconductor device of the vertical stack.

7. The semiconductor device assembly of claim 1, wherein the plurality of retention structures between each adjacent pair of semiconductor devices is configured to redirect a flow of the NCF away from the plurality of retention structures towards one or more gaps free from retention structures during a compression of the vertical stack.

8. A method of forming a semiconductor device assembly, comprising:
providing a vertical stack of semiconductor devices, the vertical stack including a plurality of electrical interconnects, a plurality of retention structures, and a non-conductive film (NCF) between each adjacent pair of semiconductor devices of the vertical stack,
compressing the vertical stack of semiconductor devices to reduce a distance between each adjacent pair of semiconductor devices of the vertical stack and to cause the NCF between each adjacent pair of semiconductor devices to flow away from the corresponding plurality of retention structures towards one or more gaps free from retention structures,
wherein the plurality of retention structures between each adjacent pair of semiconductor devices is disposed peripherally to the corresponding plurality of electrical interconnects,
wherein each of the plurality of retention structures has a height less than the distance between the corresponding adjacent pair of semiconductor devices following the compressing, and
wherein the plurality of retention structures between each adjacent pair of semiconductor devices has a smaller first average pitch between adjacent ones of the plurality of retention structures than a second average pitch between adjacent ones of the corresponding plurality of electrical interconnects.

9. The method of claim 8, wherein the plurality of retention structures between each adjacent pair of semiconductor devices includes a first region at a first peripheral edge of the vertical stack, and a second region at a second peripheral edge of the vertical stack opposite the first peripheral edge.

10. The method of claim 9, wherein a third region at a third peripheral edge of the vertical stack between each adjacent pair of semiconductor devices includes a gap free of retention structures.

11. The method of claim 10, wherein the gap is at least 25% of a length of the third peripheral edge.

12. The method of claim 10, wherein a fourth region at a fourth peripheral edge of the vertical stack between each adjacent pair of semiconductor devices includes another gap free of retention structures.

13. The method of claim 8, wherein the vertical stack further includes a plurality of electrical interconnects, a plurality of retention structures, and a non-conductive film (NCF) under a bottom semiconductor device of the vertical stack.

14. A semiconductor device assembly, comprising:
one or more semiconductor devices;
a plurality of electrical interconnects and a plurality of retention structures extending downwardly from each of the one or more semiconductor devices; and
a non-conductive film (NCF) below each of the one or more semiconductor devices of and surrounding the corresponding plurality of electrical interconnects and the corresponding plurality of retention structures,
wherein the plurality of retention structures extending from each of the one or more semiconductor devices is disposed peripherally to the corresponding plurality of electrical interconnects,
wherein at least a portion of the NCF below each of the one or more semiconductor devices extends below the corresponding plurality of retention structures, and
wherein the plurality of retention structures extending from each of the one or more semiconductor devices has a smaller first average pitch between adjacent ones of the plurality of retention structures than a second average pitch between adjacent ones of the corresponding plurality of electrical interconnects.

15. The semiconductor device assembly of claim 14, wherein the plurality of retention structures extending downwardly from each of the one or more semiconductor devices includes a first region at a first peripheral edge of the corresponding one of the one or more semiconductor devices, a second region at a second peripheral edge of the vertical stack opposite the first peripheral edge.

16. The semiconductor device assembly of claim 15, wherein a third region at a third peripheral edge between the first and second peripheral edges of the one or more semiconductor devices includes a gap free of retention structures.

17. The semiconductor device assembly of claim 16, wherein the gap is at least 25% of a length of the third peripheral edge.

18. The semiconductor device assembly of claim 16, wherein a fourth region at a fourth peripheral edge between the first and second peripheral edges of the one or more semiconductor devices includes another gap free of retention structures.

19. The semiconductor device assembly of claim 14, wherein the plurality of retention structures extending downwardly from each of the one or more semiconductor devices is configured to redirect a flow of the NCF away from the plurality of retention structures towards one or more gaps free from retention structures during a compression of the semiconductor device assembly.

20. The semiconductor device assembly of claim 14, wherein the plurality of retention structures comprise a plurality of thermal pillars, each comprising a thermally conductive metal.
